(19) United States
(12) Patent Application Publication
(10) Pub. No.: US 2003/0064582 A1
(43) Pub. Date: Apr. 3, 2003

(54) Mask layer and interconnect structure for dual damascene semiconductor manufacturing

(76) Inventors: Isaiah O. Oladeji, Gotha, FL (US); Scott Jessen, Orlando, FL (US); Joseph Ashley Taylor, Orlando, FL (US)

Correspondence Address: BEUSSE, BROWNLEE, BOWDOIN & WOLTER, P. A., 390 NORTH ORANGE AVENUE, SUITE 2500, ORLANDO, FL, 32801, US

(21) Appl. No.: 09/966,157

(22) Filed: Sep. 28, 2001

(51) Int. Cl. H01L 21/4763

(52) U.S. Cl. 438/638; 438/618

(57) ABSTRACT

A novel mask layer is used in the dual damascene construction of an interconnect structure of an integrated circuit device. The interconnect structure has a low-k dielectric material. The mask layer has a passivation film deposited on the low-k dielectric material, a barrier film is deposited over the passivation film and a metallic film is deposited over the barrier film. The metallic film increases the overall etch selectivity of the mask layer to assure a faithful transfer of via and trench features to the low-k dielectric material during the etching steps of the dual damascene process.

### BACKGROUND OF THE INVENTION

The present invention relates generally to the fabrication of interconnect structures on a semiconductor wafer. More specifically, this invention pertains to the process known as a dual damascene process used in the fabrication of interconnect structures. In addition, the invention relates to interconnect structures incorporating low-k dielectric materials.

Interconnect structures are those structures on an integrated circuit chip that connect different levels of a multi-level-interconnect integrated circuit device, and include contact holes and vias. Contact holes are holes in a PMD (pre-metal dielectric), such as a dielectric layer between a polysilicon gate and a metal layer. Vias allow electrical connections between a metal layer and the polysilicon and/or the silicon wafer substrate. Vias also allow the contact between different metal layers in an integrated circuit device.

In a copper multi-level-interconnect structure, a trench is a term used to describe a formation in a dielectric material in which copper metal is deposited to form lines. Trenches may also be utilized for the formation of buried capacitors in a dielectric material. In addition, a copper filled via may serve to interconnect copper lines on different levels of an integrated circuit.

The construction of the interconnect structure can be performed using a single damascene process. However, a dual damascene process has become increasingly popular as a method for fabrication of interconnect structures. The dual damascene process eliminates some steps from the single damascene process, thereby decreasing the fabrication time, and increasing the overall production yield of integrated circuit chips. An exemplary dual damascene process is illustrated in FIGS. 1 through 9.

With respect to FIGS. 1 through 4, an integrated circuit chip 10 is illustrated including a dielectric material deposited over a metal layer 11. The dielectric material includes the via dielectric layer 12 and the trench dielectric layer 13. The via dielectric layer 12 is deposited over an insulative barrier layer 14. The trench dielectric layer 13 is deposited over an etch stop layer 15 disposed between the via dielectric layer 12 and the trench dielectric layer 13. A photoresist material 16 overlays the trench dielectric layer 13.

Using photolithography, a via feature is patterned in the photoresist layer 16. As shown in FIG. 2, a via 17 is then etched through the dielectric layers 13, 15, and 12 to the barrier layer 14. The photoresist layer 16 is then stripped from the semiconductor device and replaced with a new or second photoresist layer 16, and a trench feature is patterned in the photoresist layer 16. As shown in FIG. 3, a trench 18 is etched through the trench dielectric layer 13 to the etch stop layer 15. The new photoresist layer 16 is then stripped. The insulative barrier layer 14, exposed in the via 17 is then selectively etched to the underlying metal layer 11. A thin copper barrier together with a copper film 19 is then deposited in the trench 18 and via 17. The semiconductor wafer is planarized using chemical mechanical planarization to form the interconnect structure shown in FIG. 4.

Dielectric materials having lower dielectric constants, known as low-k dielectric materials, have become increasingly popular in the fabrication of interconnect structures of semiconductor devices. The low-k dielectric materials typically have dielectric constants up to 3.0. These low-k dielectric materials provide a lower intra-level, and inter-level capacitance, which reduce cross talk and enhance the transfer of a signal across an integrated circuit. However, low-k dielectric materials are chemically reactive with photoresist materials, or have impurities that react with the photoresist materials when the latter comes into contact with the low-k. dielectric materials. The low-k dielectric materials are typically polymer based materials such as SILK, which is manufactured by Dow Chemical, and organosilicates such as CORAL and BLACK DIAMOND which are manufactured by Novellus and Applied Materials, respectively.

Reactions between the low-k dielectric materials and the photoresist materials are more severe during the trench formation where, apart from a surface interaction, there is also interaction within the via. This reaction then blocks the trench patterning and prevents fabrication of interconnect structures using the traditional dual damascene procedures. Accordingly, a mask layer must be formed over the low-k dielectric material before the photoresist material is deposited on the semiconductor wafer and integrated circuit chips.

A mask layer as used herein is a layer that includes a film, or composite films, that overlay a dielectric layer in an interconnect structure, and serves as a barrier layer between a photoresist layer and a dielectric layer. A mask layer may also be referred to as a hard mask layer or photoresist mask, which terms may be used interchangeably in this disclosure. The mask layer protects specific regions of the dielectric layers during the etching process.

A dual damascene process used in the construction of an interconnect structure is shown in FIGS. 5 through 9. With respect to FIG. 5, the fabrication of an interconnect structure may begin with the deposition of a dielectric material. The dielectric material depicted in FIG. 5 includes a via dielectric layer 20 and a trench dielectric layer 21. Two etch stop layers are deposited on the semiconductor chip, and serve as indicators to stop an etching process at a predetermined depth in a dielectric material. A first etch stop layer known as an insulative barrier layer 22 is formed over an underlying interconnect layer having a metal deposit as a conductive line 34.

The via dielectric layer 20 overlays the insulative barrier layer 22. An etch stop layer 23 is then formed over the via dielectric layer 20, and the trench dielectric layer 21 is deposited over the etch stop layer 23. The insulative barrier layer 22 and the etch stop layers 23 typically consist of silicon carbide (SiC) or silicon nitride (Si₃N₄).

A mask layer 24 is then deposited over the trench dielectric layer 21. The hard mask layers known in the prior art typically include two films. The two mask films may include a first mask film usually consisting of SiC or Si₃N₄ and a second mask film consisting of silicon dioxide (SiO₂). The two hard mask films prevent the photoresist materials from coming into contact with the low-k dielectric material during via and trench photolithographies and etching. In addition, the first mask film, SiC or Si₃N₄, protects the low-k dielectric films from chemical mechanical polishing. It also serves as an insulator or diffusion barrier for the metal film to be deposited in a trench and via, its function is to prevent surface current or metallic ion leaks from the conductive metal deposited in the trench. The second hard mask film serves as a sacrificial layer where the trench is initially etched; this layer will be eliminated after the completion of all processes. It also helps protects the underlying dielectric layers when the trench pattern thereon is transferred to the underlying dielectric layers.

The second mask film consists of SiO₂ separating the first mask film from a photoresist layer 25. With respect to FIG. 6, a site for the trench 27 is first patterned in the photoresist layer 25, and then etched to a predetermined depth into the mask layer 24. The photoresist layer 25 is then removed, and replaced with a fresh photoresist layer 41 filling the trench 27. With respect to FIG. 7, a via feature is patterned in the photoresist layer 25 and etched through the dielectric layers 21 and 20 and to the insulative barrier layer 22. The photoresist layer 41 is then stripped. As shown in FIG. 8, the feature for the trench 27 that was patterned in the second hard mask film is then etched through the first hard mask film and the trench dielectric layer 21 to the etch stop layer 23. Since there is no photoresist material protection, an etch chemistry is chosen such that when the trench dielectric layer 21 is being etched, the second hard mask film is not etched. In a separate etching procedure, the etch stop layer 23 within the trench 27 and the barrier insulative layer 22, within the via 28, are selectively etched so the via 28 may connect an underlying conductive line 11 to a conductive line formed in the trench 27.

With respect to FIG. 4, a copper metal is deposited within the via 28 and trench 27. The copper metal is planarized, using chemical mechanical planarization, to the first mask film.

The above-described dual damascene process is typically used with organic low-k dielectric materials; and is typically difficult to implement with organosilicate dielectric materials. In order to transfer a feature from the mask layer to the underlying dielectric layers without a photoresist layer, a higher etch selectivity is required between the mask layer and the dielectric layers. The ratios of etch rates of two different layers subject to the same etch chemistry is known as the selectivity of an etch process. The mask films consisting of SiO₂, SiC, and Si₃N₄ all have poor etch selectivity with respect to organosilicate dielectric materials independent of the etch chemistry, which results in poor or no via or trench feature transfer to the underlying dielectric layer from the hard mask layer. Poor feature transfer can result in metal line shorts or uncontrollable device behavior, which could result in lower product yield. Thus, the existing hard mask layer compositions do not effectively transfer features to the underlying dielectric layer composed of organosilicate low-k dielectric materials.

### SUMMARY OF THE INVENTION

The present invention solves the foregoing problems with the use of a novel mask layer in the dual damascene fabrication of an interconnect structure having a low-k dielectric material. A low-k dielectric material or low-k dielectric layer, as used in this specification, comprises those organosilicate dielectric materials and organic dielectric materials having dielectric constants up to about 3, for example the dielectric material having the trade name of CORAL, manufactured by Novellus, has a dielectric constant of 2.7-2.8.

A mask layer is deposited over a low-k dielectric material which overlays an underlying metallic layer. The mask layer has three films including a first mask film that serves as an insulative film and/or a passivation layer. The first mask film comprises SiO₂ and SiC. A second mask film, which is a sacrificial film, is deposited over the first mask film and comprises Si₃N₄, and serves as a barrier film between the first mask film and a third mask film. The third mask film is deposited over the second mask film, and is a metallic film preferably comprising a refractory metal such as titanium (Ti) or tantalum (Ta), or a metal alloy such as titanium nitride (TiN) or tantalum nitride (TaN). The metalization of the mask layer provides a higher etch selectivity to the mask layer with respect to the underlying dielectric materials and allows an effective feature transfer to the low-k dielectric material.

A via and trench feature are patterned and then etched using a dual damascene procedure. After the via and trench are etched within the dielectric layer, and a conductive metal is deposited therein, the conductive metal is planarized using chemical mechanical planarization. The second and third sacrificial mask films are removed during the planarization procedure, so the first mask film remains as an insulator to the conductive metal, and a passivation layer over the dielectric material.

### BRIEF DESCRIPTION OF DRAWINGS

FIGS. 1-4 depict the prior art fabrication of an interconnect structure using a dual damascene procedure.

FIGS. 5-9 depict the prior art fabrication of an interconnect structure using a dual damascene procedure wherein in a mask layer is disposed between a dielectric layer and a photoresist layer.

FIGS. 10-15 depict the dual damascene construction of an interconnect structure utilizing the present invention.

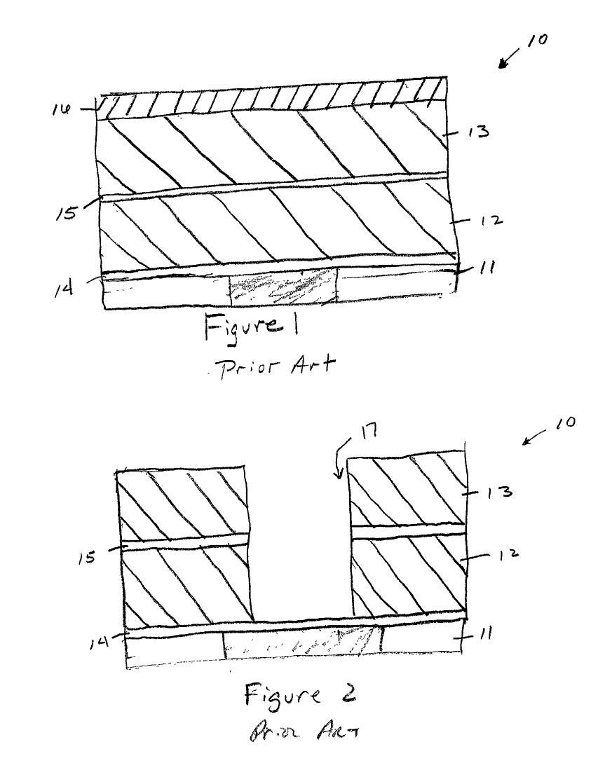

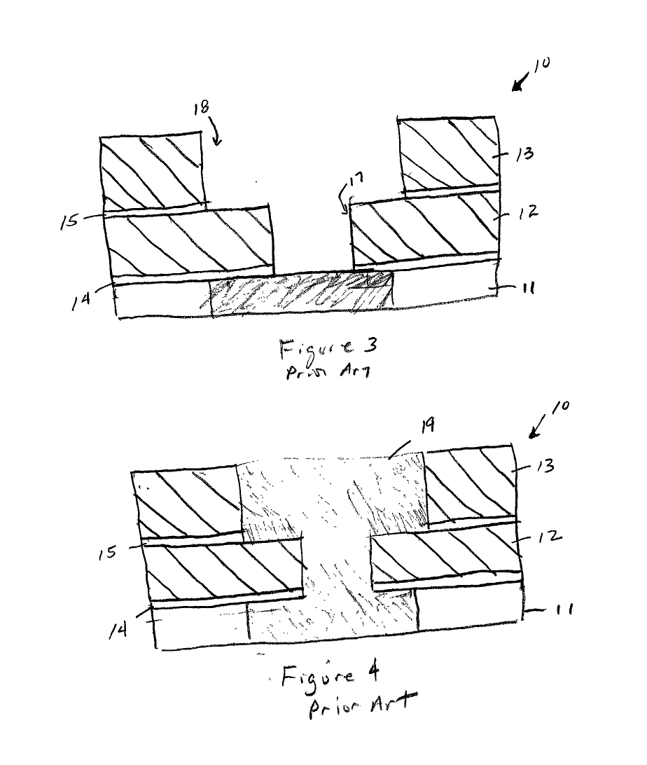

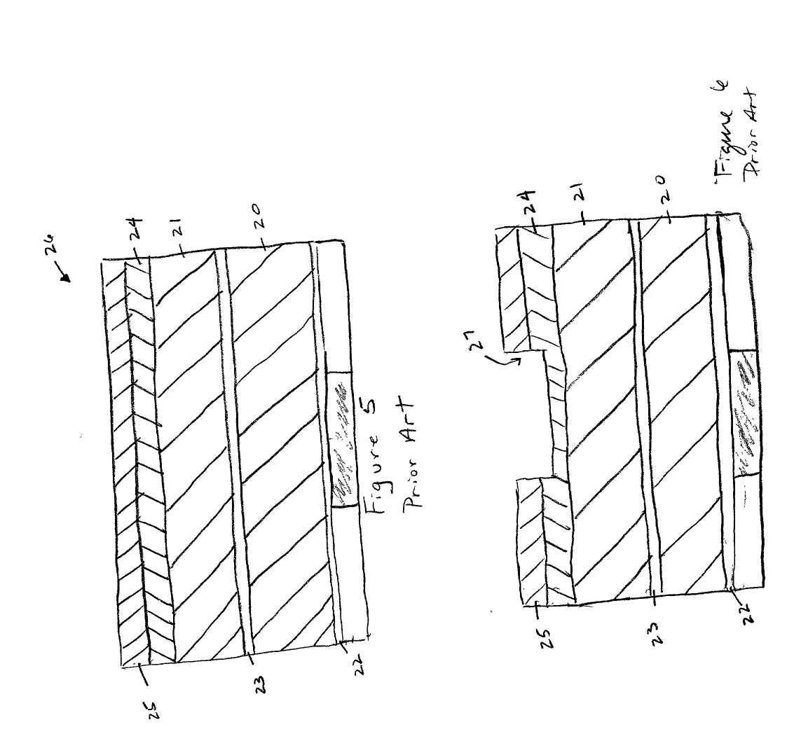

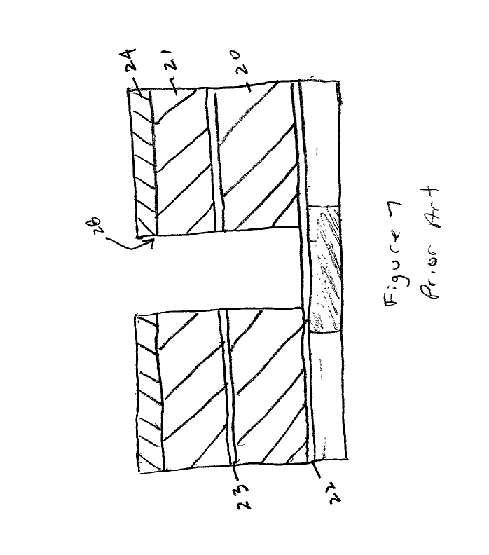

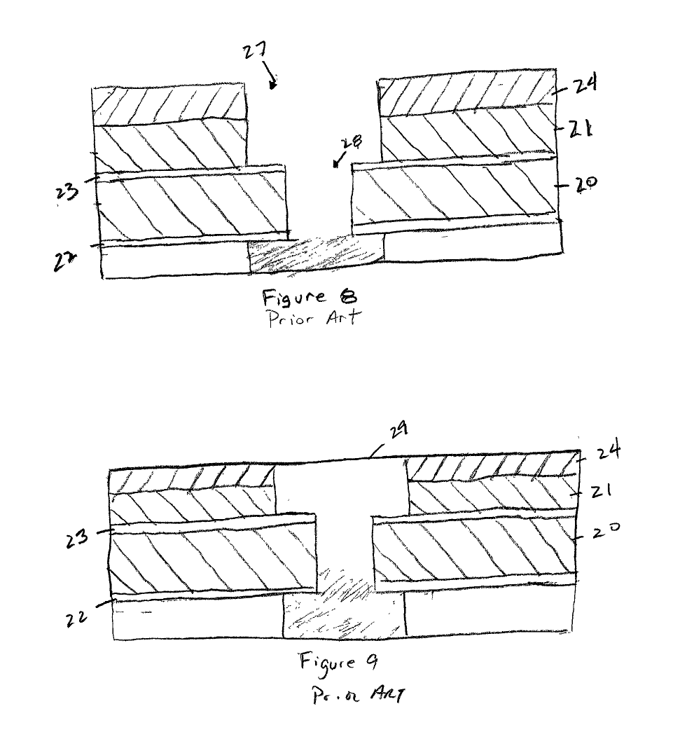

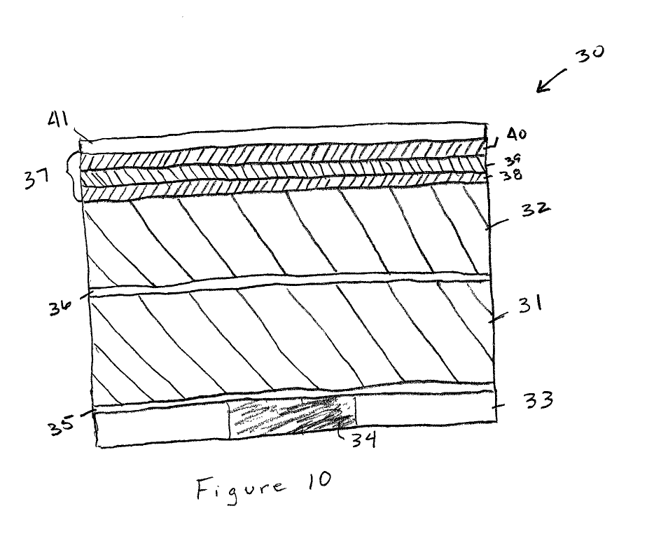

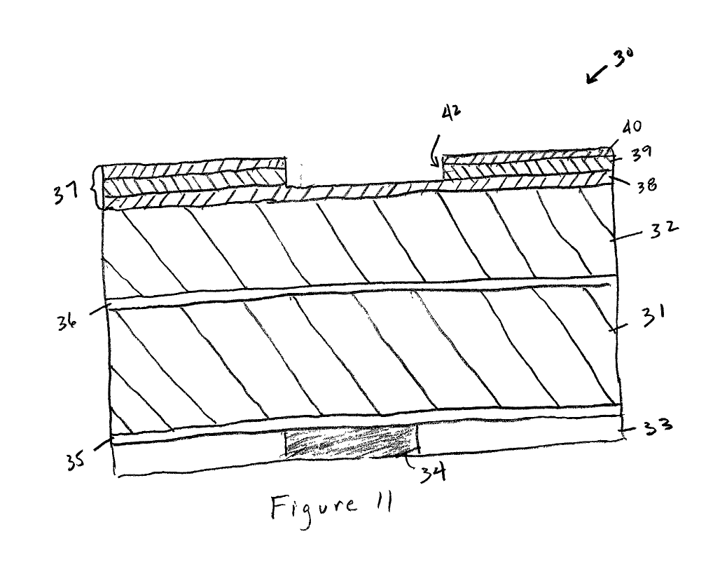

### DETAILED DESCRIPTION OF THE DRAWINGS

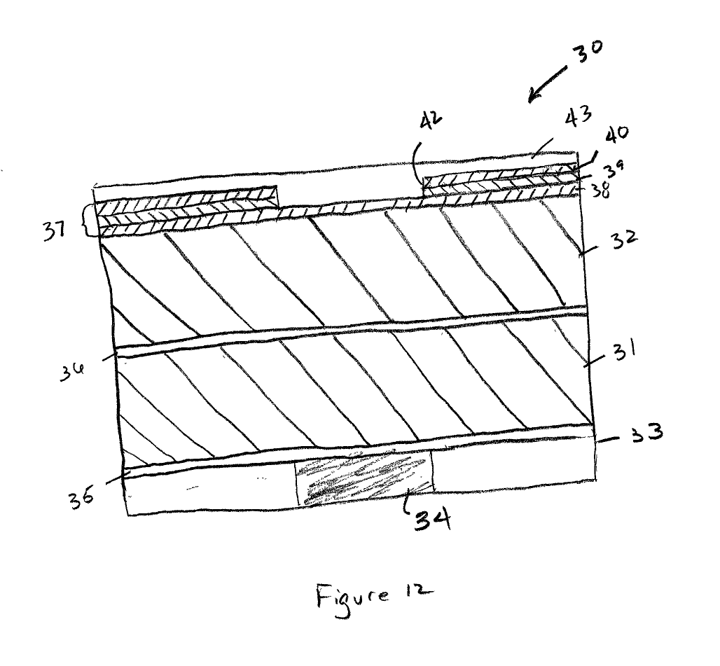

A sectional view of an interconnect layer 30 of an integrated circuit chip is shown in FIG. 10, and includes a low-k dielectric material including a via dielectric layer 31 and a trench dielectric layer 32 formed over an underlying interconnect layer 33 having a conductive metal 34. An insulative barrier layer 35, usually comprising silicon nitride or silicon carbide, is first deposited over the interconnect layer 33.

The via dielectric layer 31 is then deposited over the barrier layer 35. The via dielectric layer 31 comprises any organosilicate or organic low-k dielectric material having a dielectric constant up to about 3.0. Such low-k dielectric materials used are CORAL manufactured by Novellus, BLACK DIAMOND manufactured by Applied Materials, or SILK manufactured by Dow Chemical Company, Inc. An etch stop layer 36 is then deposited over the via dielectric layer 31. A trench dielectric layer 32 is formed over the etch stop layer 36 and comprises the same low-k dielectric material used in the via dielectric layer 31.

The via dielectric layer 31 may typically range in thickness from about 3000 to about 6000 A, and the trench dielectric layer 32 may range in thickness from 1500 A to 6000 A. The etch stop layer 36 and the insulative barrier layers have a thickness ranging up to about 500 A. These examples of film thickness are not intended to limit the present invention to such ranges of thickness. Those skilled in the art will appreciate the fact that the individual thickness of each of the films is eventually determined by various factors such as film etch rates, uniformity of etch rates and the aspect ratio of the openings formed in the dielectrics.

A mask layer 37 is then deposited over the trench dielectric layer 32. The mask layer 37 serves as a barrier between the dielectric material and a photoresist layer 41 deposited on the mask layer 37. The mask layer 37 depicted in FIG. 10 has three mask films including a first mask film 38, a second mask film 39 and a third mask film 40. The first mask film 38 is a passivation layer which may comprise of silicon dioxide or silicon carbide. By definition the passivation layer protects the underlying low-k dielectric layers 31 and 32 from contamination.

In addition, the first mask film 38 serves as an insulator. The first dielectric layer comprises a dielectric material such as silicon dioxide or silicon carbide. The first mask film remains as a component of the interconnect structure and prevents surface current leakage between conductive lines.

The second mask film 39, comprising silicon nitride, is deposited over the first mask film 38, and serves as a barrier between the silicon dioxide or silicon carbide and the third mask film 40, which is a metallic layer. The third mask film 40 preferably consists of a refractory metal such as titanium, tantalum or tungsten, or a metal alloy thereof such as titanium nitride, tantalum nitride or tungsten nitride. Inasmuch as the SiO₂, SiC, or Si₃N₄, each has a lower etch selectivity with respect to the low-k dielectric materials comprising the via dielectric layer 31 and the trench dielectric layer 32, the addition of the refractory metal in the third mask film layer 40 increases the etch selectivity of the mask layer 37. An increased etch selectivity allows the effective and faithful transfer of a via or trench feature patterned in the films 39 and 40 through the first mask film 38, the via dielectric layer 31 and the trench dielectric layer 32.

In the exemplary embodiment, the first mask film 38 may range in thickness from about 500 A to about 1000 A; the second mask film 39 may range in thickness from about 500 A to about 1000 A; and the third mask film may range in thickness from about 200 A to about 500 A. These examples of film thickness are not intended to limit the present invention to such ranges of thickness. Those skilled in the art will appreciate the fact that the individual thickness of each of the films is eventually determined by various factors such as film and mask etch rates, uniformity or of etch rates and the aspect ratio of the openings formed in the mask and dielectrics.

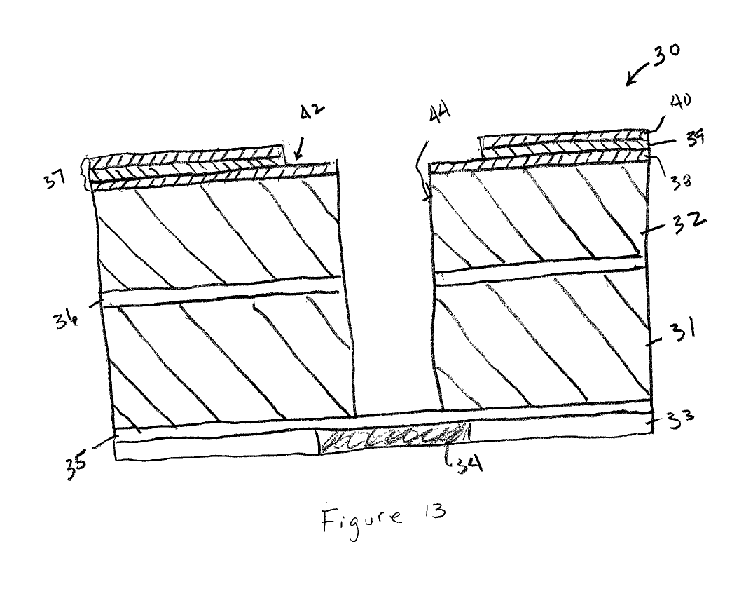

In the dual damascene process, a trench feature is first patterned in the photoresist layer 41. The patterning of trench and via features is performed using conventional photolithography methods known to those skilled in the art. With respect to FIG. 11, using a dry etching process, a trench 42 is etched in the mask layer 37, through the second and third mask films 39 and 40 to the first mask film 38. The trench 42, etched in the mask layer 37, will be further etched in the dielectric material as will be described in more detail.

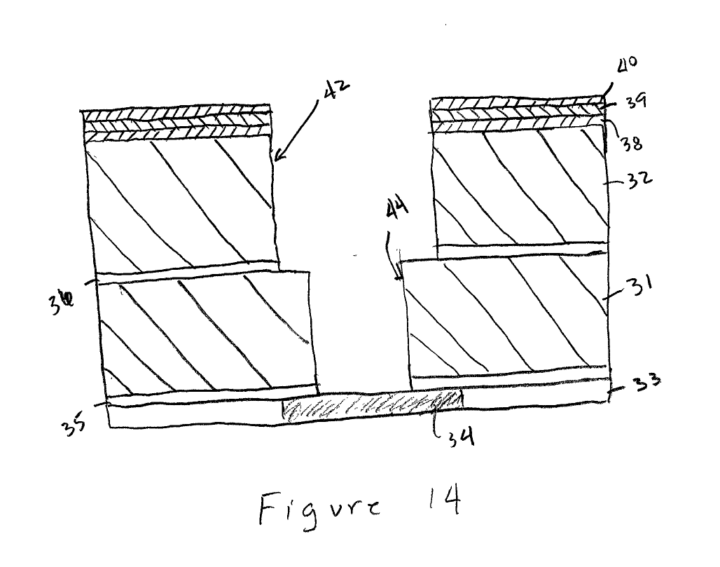

The photoresist layer 41 is then stripped from the semiconductor surface. As shown in FIG. 12, a second photoresist layer 43 is deposited over the mask layer 37. A via feature, desired to be etched in the dielectric material, is then patterned in the second photoresist layer 43. With respect to FIG. 13, using a dry etching process, a via 44 is etched in both dielectric layers 31 and 32 to a predetermined depth of the via dielectric layer 31. As shown in FIG. 13, the via 44 is etched down to the barrier layer 35. The barrier layer 35 serves to protect the underlying conductive metal 34 from the etching chemistry used when etching the via 44. It also passivates the surface of the underlying interconnect layer 33.

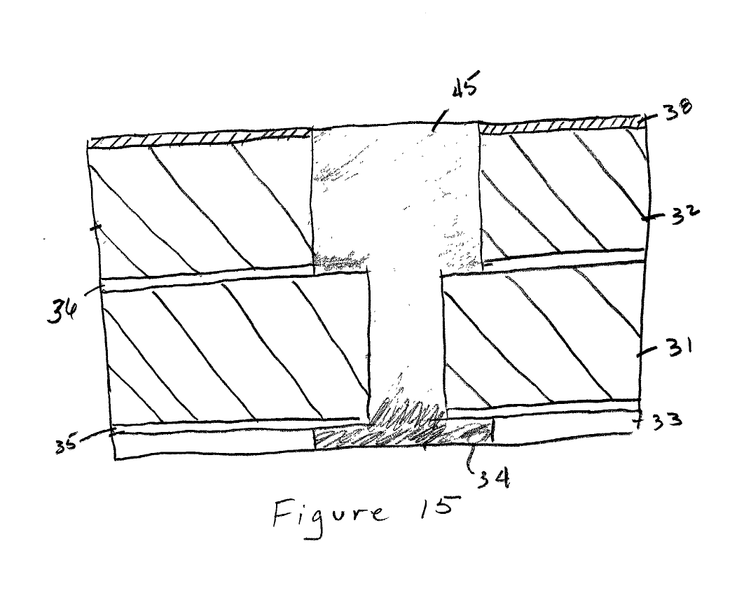

The second photoresist layer 43 is then stripped from the interconnect layer 30. Utilizing the trench previously etched into the mask layer 37, a trench 42 is then selectively etched into the low-k dielectric material to a predetermined depth of the trench dielectric layer 32, as shown in FIG. 14. The trench 42 is preferably etched down to the etch stop layer 36.

In a separate selective etching process, the portion of the barrier layer 35 within the via 44, and the etch stop layer in the trench 42, are also removed from the interconnect layer. In this manner, the conductive metal to be deposited in the via 44 will contact the metal layer 34 in the underlying interconnect structure 33, connecting two metal lines of different interconnect layers.

As shown in FIG. 15, a copper metal 45 is deposited in the via 44 and the trench 42. A thin copper barrier and copper seed are first deposited using sputtering or chemical vapor deposition techniques (CVD), which is followed by a thick copper film deposition to fill the vias 44 and trenches 42 using electroplating. Chemical mechanical planarization (CMP) is used to eliminate excess conductive metal outside the trench 42, and remove the second and third mask films 39 and 40, so the first mask film 38 remains adjacent the conductive metal 45. In this manner the interconnect structure shown in FIG. 15 is created using a dual damascene procedure, and includes a via 44 electrically connecting the underlying conductive line 34 with a conductive line formed in the trench 42.

The hard mask film of the present invention prevents the photoresist material from contacting the low-k dielectric material during via and trench photolithographies, and has a higher etch selectivity with respect to the low-k dielectric materials. A single hard mask layer of silicon dioxide or silicon nitride can expose the dielectric to the photoresist, poisoning the photoresist and preventing printing. Moreover, a dual mask film combining any two films of SiC, Si₃N₄, or SiC has an etch rate similar to the etch rate of the low-k dielectric materials. Accordingly, the patterned feature in the hard mask will not be transferred to the low-k dielectric materials.

While the preferred embodiments of the present invention have been shown and described herein in the present context, it will be obvious that such embodiments are provided by way of example only and not of limitation. Numerous variations, changes and substitutions will occur to those of skilled in the art without departing from the invention herein. For example, the present invention need not be limited to best mode disclosed herein, since other applications can equally benefit from the teachings of the present invention. Accordingly, it is intended that the invention be limited only by the spirit and scope of the appended claims.

What we claim as our invention is:

1. A mask layer overlaying a low k dielectric material deposited over an underlying metal layer of an integrated circuit device, for use in the construction of an interconnect structure of the integrated circuit device, said mask layer comprising:
(a) a passivation mask film deposited on the low-k dielectric material;
(b) a barrier mask film deposited over the passivaton mask film; and,
(c) a metallic mask film deposited over the barrier mask film.

2. The mask layer of claim 1 wherein said passivation mask film comprises silicon dioxide or silicon carbonite.

3. The mask layer of claim 1 wherein said barrier mask film comprises silicon nitride.

4. The mask layer of claim 1 wherein said metallic mask film comprises a refractory metal or a refractory metal alloy.

5. The mask layer of claim 4 wherein said refractory metal is chosen from a group of refractory metals comprising titanium, tantalum and tungsten, and said refractory metal alloy is chosen from the group of refactory metal alloys comprising titanium nitride and tantalum nitride.

6. A method of forming a dual damascene interconnect structure of an integrated circuit device, said interconnect structure having a low-k dielectric material deposited over an underlying metal layer, comprising the steps of:
(a) forming a passivation mask film over the low-k dielectric material;
(b) forming a barrier mask film over the passivation mask film;
(c) forming a metallic mask film over the barrier mask film, and said passivation barrier and metallic mask films forming a mask layer overlaying said low-k dielectric material;
(d) etching a trench within the low-k dielectric material to a predetermined depth of the low-k dielectric material; and,
(e) etching a via through the low-k dielectric material to the underlying metal layer.

7. The method of claim 6 wherein said passivation mask film comprises silicon dioxide or silicon carbonite.

8. The method of claim 8 wherein said barrier mask film comprises silicon nitride.

9. The method of claim 8 wherein said metallic mask film comprises a refractory metal or a refractory metal alloy

10. The method of claim 9 wherein said refractory metal is chosen from the group of refractory metals including titanium, tantalum and tungsten, and said refractory metal alloy is chosen from the group of refractory metal alloys comprising titanium nitride and tantalum nitride.

11. The method of claim 6 further including the step of forming a photoresist layer over the metallic mask film, patterning a trench feature in the photoresist layer, etching a trench through the metal mask film and the barrier mask film to the passivation mask film.

12. The method of claim 6 further including the step of forming a photoresist layer over the low-k dielectric material, and patterning a via feature in the photoresist layer.

13. The method of forming an interconnect structure on an integrated circuit device having a low-k dielectric material deposited over an underlying metal layer, and a mask layer deposited on the low-k dielectric material, and said mask layer having a desired etch selectivity with respect to the low-k dielectric material, the method comprising the step of forming a metallic film as part of the mask layer to increase the etch selectivity of the mask layer with respect to the low-k dielectric layer.

14. The method of claim 13 wherein said metallic film comprises a refractory metal or a refractory metal alloy.

15. The method of claim 14 wherein said refractory metal is chosen from the group of refractory metals including titanium, tantalum and tungsten and said refractory metal alloy is chosen from the group of refractory metal alloys including titanium nitride or tantalum nitride.

16. The method of claim 13 furthering including the steps of forming a passivation mask film over the dielectric material, forming a barrier mask film over the passivation mask film and said metallic film is formed over the barrier mask film.

17. The method of claim 15 wherein said passivation mask film comprises silicon dioxide or silicon carbonite.

18. The method of claim 15 wherein said barrier mask film comprises silicon nitride.

19. The method of claim 13 further including the steps of etching a trench within the low-k dielectric material to a predetermined depth of the low-k dielectric material, etching a via through the low-k dielectric material to the underlying metal layer of the low-k dielectric material, and depositing a conductive metal within the via and trench.

20. The method of claim 19 wherein the conductive metal is deposited on the integrated circuit chip outside of the via and the trench and the method further including the steps of planarizing the integrated circuit chip, and removing said excess conductive metal, the metallic mask layer and the barrier mask film.
